(19) United States
(12) Patent Application Publication
(10) Pub. No.: US 2008/0271989 A1
(43) Pub. Date: Nov. 6, 2008

(54) APPARATUS FOR PLATING AND METHOD FOR CONTROLLING PLATING

(76) Inventors: Fumito Shoji, Oita-shi (JP); Yoshio Kasai, Oita-shi (JP); Kazuhiro Murakami, Oita-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/108,296

(22) Filed: Apr. 23, 2008

(30) Foreign Application Priority Data
Apr. 25, 2007 (JP) P2007-115599

(51) Int. Cl. C23C 14/00

(52) U.S. Cl. 204/192.13; 204/298.03

(57) ABSTRACT

An apparatus for plating includes a plating bath for plating copper (Cu) film on the surface of a substrate under a prescribed plating condition using a plating solution, a chemical supplying unit for supplying each components constituting the plating solution into the plating bath, a plating solution analyzing unit for analyzing a concentration of a predetermined component contained in the plating solution, a plating controlling unit for storing correlation data between a parameter representing a state of the plating solution and the plating condition, extracting the parameter relating the plating solution, and determining the predetermined plating condition based on the parameter and the stored correlation data.

### CROSS-REFERENCE TO RELATED APPLICATIONS

This application is based upon and claims the benefit of priority from the prior Japanese Patent Application No. 2007-115599 filed on Apr. 25, 2007, the entire contents of which are incorporated herein by reference.

### BACKGROUND OF THE INVENTION

1. Field of the Invention

The present invention relates to an apparatus for plating and a method of controlling plating to form a damascene wiring structure using a plating method in a manufacturing process of a semiconductor device.

2. Description of the Related Art

It is employed as a manufacturing process of a semiconductor device to deposit a metallic film on a base metallic thin film, which is prepared by a sputtering method, by using a plating method so as to form a damascene wiring structure.

An apparatus for plating to form the metallic film by using the plating method regularly measures and monitors the concentrations of inorganic or organic components contained in a plating solution by using a method, such as titration, as disclosed in Japanese Patent Application Laid-Open Nos. 2001-240998 and 2001-73200. The concentrations of the components of the plating solution are maintained substantially constant by replenishing or discharging the plating solution based on the measurements, and therefore, plating quality may remain constant.

However, organic by-products may be derived and increased from the organic components originally contained in the plating solution by plating and circulating of the plating solution as proceeding plating on a substrate to be plated.

During plating, these organic by-products are adsorbed on the surface of the substrate to be plated like as the organic components useful for the plating and introduced into a plating film. The concentrations of the organic by-products should be regularly measured to prevent any variation in electrical properties of the plating film. However, such concentrations can not be measured by such a method as titration. In a static current plating method, which performs a voltage control to maintain a plating current constant, the properties of growth of plating films in a trench for damascene wiring may be changed by the organic by-products. As a consequence, the amount of bottom-up may decrease or the amount of impurities may increase in the plating film.

### SUMMARY OF THE INVENTION

According to a first aspect of the present invention, an apparatus for plating includes a plating bath for plating copper (Cu) film on the surface of a substrate under a prescribed plating condition using a plating solution, a chemical supplying unit for supplying each components constituting the plating solution into the plating bath, a plating solution analyzing unit for analyzing a concentration of a predetermined component contained in the plating solution, and a plating controlling unit for storing correlation data between a parameter representing a state of the plating solution and the plating condition, extracting the parameter relating the plating solution, and determining the predetermined plating condition based on the parameter and the stored correlation data.

According to a second aspect of the present invention, a method for controlling plating of the surface of a substrate with a copper (Cu) film using a plating solution, includes storing correlation data representing a correlation between a parameter representing a prescribed state of the plating solution and a plating condition, extracting the parameter relating the plating solution, determining the plating condition based on the extracted parameter and the correlation data stored, and performing plating on the substrate under the determined plating condition.

### BRIEF DESCRIPTION OF THE DRAWINGS

The accompanying drawings, which is incorporated in and constitute a part of this specification, illustrates an embodiment of the invention and together with the description, serve to explain the principles of the invention.

FIG. 1 is a view schematically illustrating an apparatus for plating according to an embodiment of the present invention;

FIG. 2 is a flow chart illustrating a plating process according to an embodiment of the present invention;

FIG. 3 is a graph illustrating a relationship between the amount of bottom-up and periods of time to use the plating solution, as an alternative to the amount of organic by-products, according to an embodiment of the present invention; and

FIG. 4 is a graph illustrating a relationship between periods of time to use the plating solution and the amount of impurities according to an embodiment of the present invention.

### DETAILED DESCRIPTION OF THE EMBODIMENTS

Reference will now be made in detail to the present embodiment of the invention, an example of which is illustrated in the accompanying drawing.

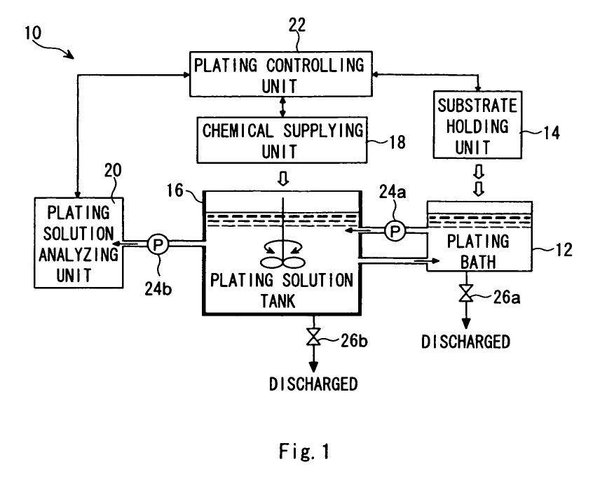

Hereinafter, embodiments of the present invention will be described in more detail with reference to accompanying drawings. FIG. 1 is a view schematically illustrating an apparatus for plating. An apparatus for plating 10 includes a plating bath 12 for plating the surface of a substrate, such as a silicon (Si) wafer, with copper plating film (Cu film), a substrate holding unit 14 for holding the substrate and accessing the plating bath 12, a plating solution tank 16 for mixing a plating solution, as necessary, and circulating the plating solution between the plating bath 12 and the solution tank 16, and a chemical supplying unit 18 for replenishing the plating solution tank 16 with chemicals containing components of the plating solution. The apparatus for plating 10 may further include a plating solution analyzing unit 20 for analyzing the concentrations of predetermined components in the plating solution during plating and a plating controlling unit 22 for controlling the entire operations of the apparatus for plating 10.

FIG. 1 also shows a pump 24a for circulating the plating solution between the plating bath 12 and the plating solution tank 16, a pump 24b for conveying the plating solution from the plating solution tank 16 to the plating solution analyzing unit 20, a valve 26a for discharging the plating solution from the plating bath 12 outwards, and a valve 26b for discharging the plating solution from the plating solution tank 16 outwards. Operations of the pumps 24a and 24b and the valves 26a and 26b are controlled by the plating controlling unit 22.

The chemical supplying unit 18 supplies chemicals to the plating solution tank 16 in response to a command signal from the plating controlling unit 22. The chemicals contain a copper sulfate base solution, a solution necessary to replenish the plating solution with various organic or inorganic components for promoting the growth of plating films in trench for wiring upon plating, and pure water for diluting. The chemicals are applied as a new plating solution initially supplied and prepared to have a prescribed composition, replenishing solutions to be regularly replenished for the plating solution (hereinafter, referred to as “regular replenishing solution”), and solutions for adjusting the concentration of each component in the plating solution. The present invention may be configured so that the chemical supplying unit 18 may supply the chemicals to the plating bath 12.

The regular replenishing solution regularly supplies a predetermined amount of the copper sulfate base solution or other solutions, because concentration of copper (Cu) ions in the plating solution is lowered and the amount of inorganic and organic components in the plating solution diminishes during plating on a substrate, and therefore, the plating solution needs to be regularly replenished with.

On the other hand, it is required to maintain the entire amount of the plating solution for plating approximately constant and reduce the concentrations of organic by-products generated by plating or circulating of the plating solution. The valves 26a and 26b are provided to regularly discharge a prescribed amount of plating solution from the plating solution tank 16 or the plating bath 12 outwards (hereinafter, the plating solution thusly discharged is referred to as “regular discharging solution”).

The plating solution analyzing unit 20 periodically measures the concentrations (N) of prescribed components constituting the plating solution, for example, by a titrimetric method, to monitor the state of the plating solution in response to a command signal from plating controlling unit 22. Although the plating solution analyzing unit 20 has been configured to collect some of the plating solution from the plating solution tank 16 for concentration analyzing as shown in FIG. 1, the present invention is not limited thereto. For example, the plating solution analyzing unit 20 may collect some of the plating solution from the plating bath 12 or a pipe for circulating placed between the plating bath 12 and the plating solution tank 16.

As described above, the plating controlling unit 22 controls operations of each unit such as the chemical supplying unit 18 and the plating solution analyzing unit 20. The plating controlling unit 22 stores the acceptable concentration ranges (hereinafter, referred to as “management ranges”) of various components contained in the plating solution actually used during plating (i.e. the plating solution to be brought in contact with the substrate) and prescribed target concentrations (T) for the components constituting the plating solution within the management range in order to facilitate to maintain the quality of plate films and plating properties constant.

This management range is determined in terms of a fact that plating with a plating solution of a composition out of the management range fails to obtain plating films with desired characteristics despite changing plating conditions, such as plating current values and the number of rotations of substrate. On the contrary, plating with a plating solution whose composition lies within the management range may acquire desired characteristics by changing such plating conditions. The target concentration (T) may be changed within the management ranges.

The plating controlling unit 22 further stores periods of time to use the plating solution (t), the number (n) of substrates to be plated with the plating solution (hereinafter, referred to as “the number (n) of plated substrates), and the amount of coulombs (c) consumed during plating using the plating solution.

The periods of time to use the plating solution (t) is determined by counting time lapsing from a time when the plating controlling unit 22 transmits a command signal for supplying a new plating solution to the plating solution tank 16 to the chemical supplying unit 18 or a time when the supply of the new plating solution to the plating solution tank 16 ends.

After a new plating solution is supplied to the plating solution tank 16, the number (n) of plated substrates using the plating solution is determined by the number of times by which the substrate holding unit 14 accesses the plating bath 12. The number (n) of plated substrates is reset when the plating solution is entirely exchanged into new one, but not when some chemicals are added to adjust the concentrations of the components in the plating solution.

The amount of consumed coulombs (c) means the amount of coulombs consumed during plating after the plating solution is newly supplied to the plating solution tank 16, and this can be calculated by the magnitude of a current generated during plating and the period of time during which the current is applied. The amount of coulombs has a very close relationship with the concentration of copper (Cu) ions in the plating solution.

The plating controlling unit 22 further stores the total amount (S) of the regular replenishing solution and the total amount (D) of the regular discharging solution. These values are reset when the plating solution is entirely exchanged into new one. The plating controlling unit 22 may store the amount of the regular replenishing solution that has been replenished once, and the number of times of replenishing, and the amount of the regular discharging solution that has been discharged once and the number of times of discharging, on behalf of the total amounts S and D. The total amount (S) of the regular replenishing solution and the total amount (D) of the regular discharging solution may affect the concentration (N) of components.

The concentrations (N) of components, the periods of time to use the plating solution (t), the number (n) of plated substrates, the amount (C) of consumed coulomb, the total amount (S) of regular replenishing solution, and the total amount (D) of regular discharging solution are parameters that represent the state of a plating solution, and therefore, these parameters are called “state parameters of plating solution”. Although the target concentrations (T) are not a parameter that represents the state of a plating solution, the target concentrations (T) may be used on behalf of the concentrations (N) of components to determine the plating conditions as will be described later, so that the target concentrations (T) might be also included in the state parameters of plating solution.

The plating controlling unit 22 may further include a database that stores data representing a relationship between two plating conditions, such as “plating current values (I)” and “the number of rotations of the substrate (R)”, and the state parameters of plating solution N, T, t, n, C, S, and D. The data are previously obtained during a plating experiment (test) and stored at the database. These preset data are used to constantly maintain electrical properties in through-hole interconnections by keeping constant one or plural characteristics selected from the amount of bottom-up in trench for wiring such as damascene wiring, the amount of impurities induced in plating films and originating from elements C, S, Cl, O, and N constituting organic components in the plating solution, overplating, and the amount of defections in plating films.

For example, correlation data are used as the preset data to generally acquire all of the plating properties such as the amount of bottom-up in good condition averagely when the apparatus for plating 10 operates on. Such correlation data may be used in performing plating especially focusing on maintaining the amount of bottom-up constant that may facilitate to maintain the amount of bottom-up constant, for example, by an operator of the apparatus for plating 10 changing set-ups.

Hereinafter, a method for controlling plating will be described, which uses the apparatus for plating 10. It should be understood that parameters S and D are represented as parameter N from the fact that parameters S and D have an effect on parameter N.

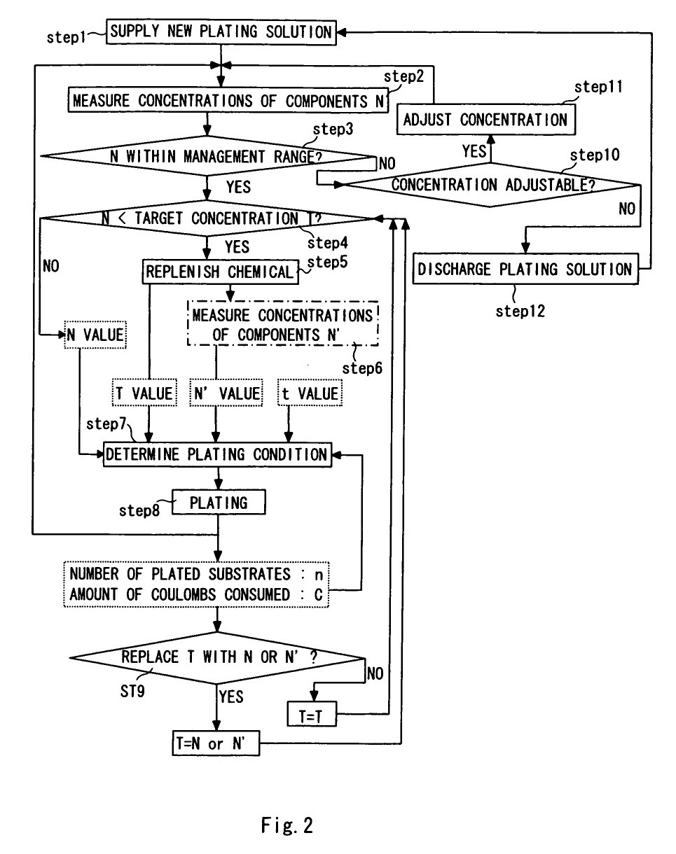

FIG. 2 is a flowchart illustrating a process of controlling plating. First, a necessary amount of plating solutions are newly supplied to the plating solution tank 16, each component of which is prepared to have a prescribed concentration (step 1). In step 1, the periods of time to use the plating solution (t) starts to count, and the number (n) of plated substrates and the amount (c) of coulombs are reset.

After the plating solution has been newly supplied to the plating solution tank 16, supplying of the regular replenishing solution and discharging of the regular discharging solution are carried out at a constant interval without respect to plating on a substrate. The time during which supplying of the regular replenishing solution and discharging of the regular discharging solution are performed varies with steps ST2 to ST12 to be described below and therefore it does not appear in FIG. 2.

After step 1, the concentrations N of the components in the plating solution are measured (step 2). Plating with the plating solution supplied in step 1 is performed several times. The plating solution cannot be discarded after the substrate holding unit 14 accessed the plating bath 12 only once as will be described later. And, during plating, the concentrations N of the components in the plating solution are arbitrarily measured (step 2). Therefore, in the steps after step 2 to be described later, it does not care whether the plating solution is the one that was newly supplied right after step 1 or the one that has been already used for plating several times.

After step 2, it is determined whether the concentrations N of components obtained in step 2 lie within management ranges (step 3). If such measuring in step 2 were performed for a plurality of components, the concentrations of all the components would be necessary to maintain the concentration of each component within each management range predetermined for the component. Accordingly, it is determined as “NO” in step 3 unless the concentration of at least one component lies within the management range.

A case will be described below where the concentrations N escape from the management ranges (“NO” in step 3). Subsequently to the determination in step 3, it is determined whether it is possible to adjust the compositions of the plating solution (step 10). If possible (“YES” in step 10), then a prescribed chemicals are supplied from the chemical supplying unit is (step 11) and then the concentrations N of the components adjusted are measured again (step 2). If impossible (“NO” in step 10), then the plating solution is discharged from the plating bath 12 and the plating solution tank 16 (step 12) and then a new plating solution is supplied to the plating solution tank 16 (step 1).

If the concentrations N lie within the management ranges (“YES” in step 3), then it is determined whether the concentrations N of the components are smaller than the target concentrations T (step 4). If the concentrations N of the components are smaller than the target concentration T (“YES” in step 4), then the corresponding chemical is replenished in the plating solution tank 16 so that the concentrations N of the component is equal to the target concentration T (step 5).

The amount of the chemicals to be replenished in step 5 may be calculated from the concentrations N of the components prior to the replenishment of the chemicals, the target concentrations T, the amount of the plating solution under use, and the concentrations of the components in the chemical. Accordingly, it could be performed to determine the plating conditions (step 7) by considering the concentrations N of the components as the target concentrations T. However, concentrations N′ of the components may be also measured like as step 2 after step 5 in terms of managing the plating solution in a strict manner (step 6).

In step 4, if the concentration N of the component is more than the target concentration T (“NO” in step 4), then it can be possible to manufacture a plating solution whose concentration accesses the target concentration T, with the amount of the plating solution remaining constant, as necessary, by discharging the plating solution from the plating solution tank 16 and diluting the plating solution by pouring pure water or aqueous solution of copper sulfate in the plating solution tank 16. However, such an adjustment may cause the concentrations of the other components to be lowered, and therefore, procedure progresses to determination of plating conditions (step 7) without the adjustment of the concentration.

The plating controlling unit 22 determines the plating conditions (step 7) by matching prescribed correlation data stored at the plating controlling unit 22 to one or plural parameters selected from the periods of time to use the plating solution (t) being counted after the plating solution in-use is supplied to the plating solution tank 16 in step 1, the number (n) of the substrates plated with the plating solution, the amount of coulombs (c) consumed for plating of the n substrates, and the concentrations N of the components, T, or N′ determined depending on which route has been undergone from step 4 to step 6.

In determining the plating current value I, with the number of rotations of substrate R constant, the plating controlling unit 22 may determine the plating current value I by finding out correlation data, which represents that among the parameters N, t, n, and C already known in step 7, the parameters t, n, and C are equal or similar and plating films with target qualities can be obtained from the relationship between N and I, and applying N to the correlation data.

Thus the plating conditions are determined in step 7, then the substrate holding unit 14, which serves to hold a substrate to be plated, accesses the plating bath 12, and then plating starts (step 8). After step 8, the process returns to measurement of the concentrations of the components in step 2. The number (n) of plated substrates and the amount C of coulombs are updated to be used for determining next plating conditions. Updating of n and C may be performed right shortly after step 8 has finished.

On the contrary, in step 7, the number R of rotations of substrate may be determined with the plating current value I remaining constant, or the plating current value I and the number R of rotations of substrate may be simultaneously determined with both the plating current value I and the number R of rotations of substrate balanced. In addition, a temperature of the plating solution may be used as the plating condition. In this case, correlation data is needed that correlates the temperature of the plating solution with the state parameters of plating solution.

Repetitive plating on the substrates, supplying of the regular replenishing solution, and discharging of the regular discharging solution may lead to variation to each of the concentrations of the components and component balance of each components in the plating solution. Accordingly, the target concentrations T may vary depending on the concentrations N of the components (“NO” in step 4, therefore, plating is executed) and the concentrations N′ of the components (step 5 is executed).

FIG. 2 shows a flowchart determining modification of the target concentrations T (step 9) after step 8. Unless the target concentrations T have been changed, the original target concentrations T are used in step 4, and, if changed, step 4 is executed while the target concentrations T are substituted with concentrations N or N′ of the components. The determination of modification of the target concentrations T may be performed after supplying of the regular replenishing solution or discharging of the regular discharging solution not shown in FIG. 2.

Even in plating according to the flowchart shown in FIG. 2, some organic by-products may be derived from the organic components originally contained in the new plating solution and increase during repetitive plating on the substrate and circulating of the plating solution between the plating bath 12 and the plating solution tank 16. As described above, these organic by-products are difficult to detect by periodic component concentration analyzing methods performed by the plating solution analyzing unit 20 in step 2, and may have a negative effect on growing properties of plating film and electrical properties of formed plating films.

However, plating illustrated in FIG. 2 may form plating films with constant qualities without any necessity of maintaining the plating conditions constant as before since the state parameters of the plating solution are arbitrarily used to determine the plating conditions in step 7, so that the amount of bottom-up becomes constant in trench for wiring such as damascene wiring and the electrical properties in trench wiring are constant.

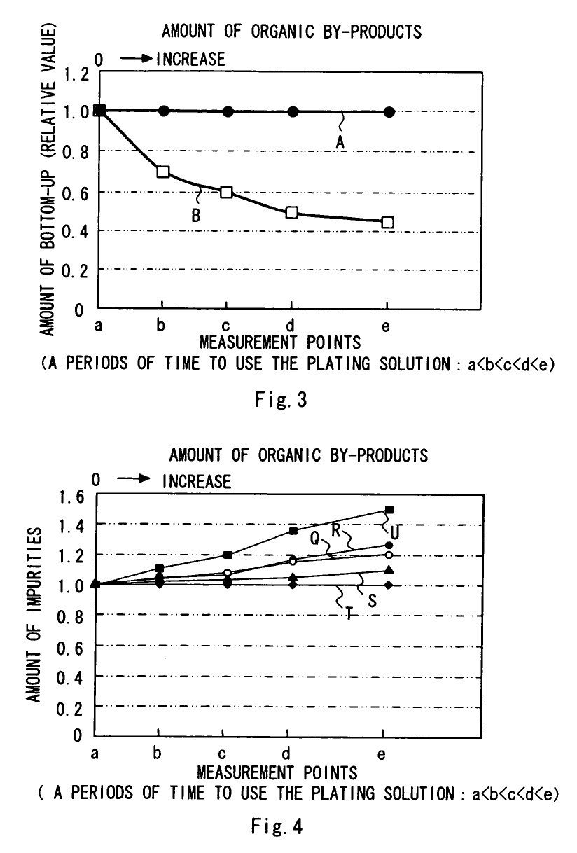

FIG. 3 shows a relationship, which is represented as line B, between the amount of bottom-up in trench for wiring and the amount of organic by-products derived from organic components contained in the plating solution to promote the growth of plating films, in a case where plating is performed, with plating conditions, such as plating current value I and the number of rotations of substrate R, remaining constant (i.e. in a case where plating is executed without performing step 7 shown in FIG. 2).

Referring to FIG. 3, the amount of bottom-up used for plating right after plating solution has been newly supplied is set as “1”, and the amount of bottom-up thereafter has a relative value. The amount of bottom-up is measured at points a, b, c, d, and e, where the periods of time to use the plating solution are set to be a<b<c<d<e. This is because the organic by-products are not contained in the new plating solution and, if produced, difficult to analyze. However, it is clear that the amount of the by-products increases over time length, for which the plating solution has been used, and therefore, it can be considered to replace the amount of the organic by-products with the periods of time to use the plating solution. However, measurement points were marked along the vertical axis of FIG. 3 since the increase in the amount of generated organic by-products is not only dependent on the periods of time to use the plating solution.

It can be seen that as the periods of time (t) to use the plating solution increase, the amount of organic by-products increases and the amount of bottom-up decreases correspondingly.

Line A in FIG. 3 represents a relationship between the amount of the organic by-products and the amount of bottom-up in trench for wiring in a case where the plating conditions are arbitrarily determined properly using the state parameters of plating solution in step 7 according to a plating process shown in FIG. 2. In this case, the plating conditions are adjusted by raising the plating current value I as the amount of organic by-products increases, and the amount of bottom-up may remain constant with this adjustment despite the increase of the amount of organic by-products.

As described above, the amount of bottom-up may remain constant by increasing the plating current value I as the amount of the organic by-products increases. Another effective method of constantly maintaining the amount of bottom-up includes making the organic components in the plating solution highly concentrated to promote the growth of the plating films, making the organic components lowly concentrated to prohibit the growth of the plating films, reducing the substrate rotational speed (reduction in the number of rotations), and increasing the amount of the copper sulfate base solution to be regularly replenished.

FIG. 4 shows a relationship, which is represented as line U, between the amount of impurities contained in a plated copper (Cu) film in trench for wiring and the amount of organic by-products yielded from organic components contained in a plating solution to promote the growth of the plating film in a case where plating is performed, with plating conditions, such as plating current value I and the number of rotations of substrate R, remaining constant (i.e. in case where plating is executed without performing the step 7 shown in FIG. 2).

Referring to FIG. 4, the amount of impurities used for plating right after plating solution has been newly supplied is set as “1”, and the amount of impurities thereafter has a relative value. In measuring the amount of impurities, measurement points of the organic by-products are marked along the vertical axis as in the case of the amount of bottom-up described above.

It can be seen that as the periods of time (t) to use the plating solution increase, the amount of organic by-products increases correspondingly and the amount of the impurities also increases. Since as the organic components affecting the growth or prohibition of plating becomes different, the molecular weights or structures of produced organic by-products also become different, the amount of the organic by-products introduced in the plating films changes, and the tendency that the amount of the impurities in the plating films increases or decreases according to the periods of time (t) to use the plating solution may also be changed. In the case of the organic components used for this embodiment, the amount of impurities increases with the periods of time to use the plating solution (t).

Line Q of FIG. 4 represents a relationship between the amount of the organic by-products and the amount of impurities in a case where the concentrations N of the component of the components are only used as the state parameters of plating solution and a plating current value I is only included in the feedback controllable plating conditions in step 7 according to a plating process shown in FIG. 2. It can be seen that variation in the amount of impurities may be greatly improved compared to line U, but not completely prohibited.

Next, the concentrations N of the components remained constant within the management range, and the amount of coulombs C consumed during plating was used as the state parameters of plating solution, which was added after the plating solution has been completely discharged and then a new plating solution with a prescribed composition has been injected. Line R represents a relationship between the amount of organic by-products and the amount of impurities in a case where the plating current value I is only included as the feedback controllable plating conditions. It can be seen that variation in the amount of impurities can not be completely prohibited because the amount of impurities is slightly larger than that in line Q, however, the variation can be greatly improved compared to line U.

This means the organic by-products can be produced by plating as well as circulating of the plating solution and the amount thereof can increase according to the amount of plating. Accordingly, the same result can be obtained although the number (n) of plated substrates is used as the state parameters of plating solution.

Similarly, frequent exchanging of the plating solution as well as the periods of time to use the plating solution (t) is effective to prohibit variation in the amount of impurities. And, it is also effective to increase the amount of the regular discharging solution D that is regularly discharged from the plating bath and the amount of the regular replenishing solution S that is regularly supplemented in the plating bath.

Line S represents a relationship between the amount of organic by-products and the amount of impurities in a case where the concentrations N of the components and the amount of consumed coulombs C are used as the state parameters of plating solution and the plating current value I is only used as the feedback controllable plating conditions. It can be seen that variation in the amount of impurities is clearly decreased compared to lines Q and R which represent only one parameter.

Line T represents a relationship between the amount of organic by-products and the amount of impurities in a case where concentrations N of the components and the amount of consumed coulombs C are used as the state parameters of plating solution and the plating current value I and the number of rotations of substrate R are used as the feedback controllable plating conditions. It can be seen that the amount of impurities nearly remains constant without respect to the amount of by-products, i.e. the periods of time to use the plating solution t.

These results show the amount of bottom-up can be easily controllable by the plating current value I as the plating conditions but the amount of impurities contained in the plating film are very difficult to control. In addition, it can be seen that it is necessary to use more parameters N, T, t, n, C, S, and D and feedback more plating conditions (plating current value I, the number of rotations of substrate R) in order to maintain the amount of impurities constant.

Although the embodiments of the present invention have been described above, the present invention is not limited thereto.

In the above embodiments, the plating conditions have been determined to maintain the amount of bottom-up and the amount of impurities constant. But, the present invention is not limited thereto, and for example the plating conditions may be determined to maintain overplating or the amount of defections in plating films constant.

For example, it has been described above with reference to FIG. 2 that the plating solution is discharged from plating bath 12 and plating solution tank 16 only when it is determined it is impossible to adjust the composition in the plating solution in step 10. However, it can be also configured that the rest of the plating solution can be discharged from plating bath 12 and plating solution tank 16 even when the periods of time (t) to use the plating solution exceed a prescribed time considering the deterioration of the plating solution overtime, the amount of consumed coulombs C exceeds a prescribed amount, the number of processed substrates n exceeds a prescribed number, and each of the total amount S of the regular replenishing solution and the total amount D of the regular discharging solution exceeds a prescribed amount.

Moreover, it is not necessary that the concentrations N of the components should be measured after every end of plating (step 8). For example, the concentrations N of the components can be measured after plating (step 8) has been performed several times, when the periods of time (t) to use the plating solution exceed a prescribed time, the amount of consumed coulombs C exceeds a prescribed amount, or the number (n) of processed substrates exceeds a prescribed number.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. An apparatus for plating comprising:
a plating bath for plating copper (Cu) film on the surface of a substrate under a prescribed plating condition using a plating solution;
a chemical supplying unit for supplying each components constituting the plating solution into the plating bath;
a plating solution analyzing unit for analyzing a concentration of a predetermined component contained in the plating solution; and
a plating controlling unit for storing correlation data between a parameter representing a state of the plating solution and the plating condition, extracting the parameter relating the plating solution, and determining the predetermined plating condition based on the parameter and the stored correlation data.

2. The apparatus for plating according to claim 1, further comprising: a plating solution tank for circulating the plating solution between the plating solution tank and the plating bath.

3. The apparatus for plating according to claim 2, wherein each of components constituting the plating solution is supplied from the chemical supplying unit to the plating bath through the plating solution tank.

4. The apparatus for plating according to claim 1, wherein the parameter representing the state of the plating solution includes any one or plural ones of
a concentration of each of components constituting the plating solution,
a periods of time to use the plating solution after a new plating solution is supplied to the plating bath,
a number of substrates plated after the new plating solution is supplied to the plating bath,
an amount of coulombs consumed after the new plating solution is supplied to the plating bath,
an amount of chemicals regularly replenished to the plating bath, and
an amount of the plating solution to be regularly discharged from the plating bath.

5. The apparatus for plating according to claim 4, wherein the parameter is provided in plurality.

6. The apparatus for plating according to claim 1, wherein the plating condition includes any one or plural ones of a current value during plating, a number of rotations of substrate during plating, and a temperature of the plating solution.

7. The apparatus for plating according to claim 6, wherein the plating condition includes the current value during plating and the number of rotations of substrate during plating.

8. The apparatus for plating according to claim 1, wherein the plating controlling unit stores a management range and a target concentration, the management range representing a acceptable range for a concentration of each component contained in the plating solution, the target concentration being determined for each predetermined component within the management range.

9. The apparatus for plating according to claim 1, wherein the plating controlling unit determines the predetermined plating condition based on the correlation data, under any one or plural ones of properties selected from the amount of bottom-up in through-hole interconnections, the amount of impurities in a plating film, overplating, and the amount of defections in the plating film, maintained constant.

10. A method for controlling plating of the surface of a substrate with a copper (Cu) film using a plating solution, comprising:
storing correlation data representing a correlation between a parameter representing a prescribed state of the plating solution and a plating condition;
extracting the parameter relating the plating solution;
determining the plating condition based on the extracted parameter and the correlation data stored; and
performing plating on the substrate under the determined plating condition.

11. The method according to claim 10, wherein the parameter includes any one or plural ones of
a concentration of each of components constituting the plating solution,
a periods of time to use the plating solution,
a number of substrates plated by the plating solution,
an amount of coulombs consumed during plating with the plating solution,
an amount of chemicals regularly replenished, and an amount of the plating solution regularly discharged.

12. The method according to claim 11, wherein the parameter is provided in plurality.

13. The method according to claim 10, wherein the plating condition comprises any one or plural ones of a current value during plating, a number of rotations of substrate during plating, and a plating temperature.

14. The method according to claim 13, wherein the plating condition includes the current value during plating and the number of rotations of substrate during plating.

15. The method according to claim 10, wherein the plating condition is determined based on the correlation data, under any one or plural ones of properties selected from the amount of bottom-up in through-hole interconnections, the amount of impurities in a plating film, overplating, and the amount of defections in the plating film, maintained constant.

16. The method according to claim 15, wherein a concentration of component of the plating solution is used as the parameter to maintain the amount of bottom-up constant and a plating current value is determined by the correlation data.

17. The method according to claim 15, wherein a plurality of parameters are used to maintain the amount of impurities in the plating film constant and the plating condition is determined based on the correlation data.

18. The method according to claim 17, wherein the parameter includes at least a concentration of component of the plating solution and an amount of coulombs consumed during plating by the plating solution.

19. The method according to claim 17, wherein the plating condition includes one or both of a current value during plating and a number of rotations of substrate during plating.

20. The method according to claim 19, wherein the plating condition is the current value during plating and the number of rotations of substrate during plating.
